(19) United States
(12) Patent Application Publication
(10) Pub. No.: US 2025/0285862 A1
(43) Pub. Date: Sep. 11, 2025

(54) SPUTTERING TARGET, SPUTTERING APPARATUS INCLUDING THE SPUTTERING TARGET, AND METHOD FOR MANUFACTURING DISPLAY DEVICE USING THE SPUTTERING TARGET

(71) Applicant: Samsung Display Co., LTD., Yongin-si (KR)

(72) Inventors: Hyeon Woo SHIN, Yongin-si (KR); Dong Hwan KIM, Yongin-si (KR); Tae Woo KIM, Yongin-si (KR); Jae Hoon CHOI, Yongin-si (KR)

(73) Assignee: Samsung Display Co., LTD., Yongin-si (KR)

(21) Appl. No.: 18/934,903

(22) Filed: Nov. 1, 2024

(30) Foreign Application Priority Data
Mar. 11, 2024 (KR) 10-2024-0033838

(51) Int. Cl. H01L 21/02; C23C 14/14; H10K 59/12

(52) U.S. Cl. CPC H01L 21/02631; C23C 14/14; H01L 21/02565; H10K 59/1201

(57) ABSTRACT

A sputtering apparatus according to an embodiment includes a chamber providing a sputtering space, a sputtering target mounted in the chamber, and including a sputtering material, and a target substrate facing the sputtering target, wherein the sputtering target includes a first sputtering target segment disposed in a first portion and a second sputtering target segment disposed in a second portion, and a composition ratio of the sputtering material in the first sputtering target segment is different from a composition ratio of the sputtering material in the second sputtering target segment.

### CROSS-REFERENCE TO RELATED APPLICATION(S)

This application claims priority to and benefits of Korean Patent Application No. 10-2024-0033838 under 35 U.S.C. § 119, filed on Mar. 11, 2024, in the Korean Intellectual Property Office, the entire contents of which are incorporated herein by reference.

### BACKGROUND

### 1. Technical Field

Embodiments relate to a sputtering target, a sputtering apparatus including the sputtering target, and a method for manufacturing a display device using the sputtering target.

### 2. Description of the Related Art

A semiconductor device may include a semiconductor element formed by a thin film deposition process such as a sputtering method. For example, a display device, which is a type of semiconductor device, may include a transistor formed by the thin film deposition process.

The transistor may be formed by the thin film deposition process using a sputtering apparatus or the like, an etching process for patterning the deposited thin film, and the like. For example, the active layer of the transistor may be formed by depositing a thin film including a semiconductor material to be used in the formation of the active layer on a manufacturing substrate for manufacturing a display panel of the display device and then etching the thin film. The manufacturing efficiency of the semiconductor device, such as the display device, manufactured using the thin film deposition process may vary according to the uniformity of the thin film.

### SUMMARY

Embodiments provide a sputtering target capable of improving the uniformity of a thin film formed on a target substrate, a sputtering apparatus including the same, and a method for manufacturing a display device using the sputtering target.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a sputtering apparatus including, a chamber providing a sputtering space, a sputtering target mounted in the chamber, and including a sputtering material, and a target substrate facing the sputtering target, wherein the sputtering target may include a first sputtering target segment disposed in a first portion and a second sputtering target segment disposed in a second portion, and a composition ratio of the sputtering material in the first sputtering target segment may be different from a composition ratio of the sputtering material in the second sputtering target segment.

In an embodiment, the sputtering apparatus may further include a shield disposed between the sputtering target and the target substrate and exposing a thin film deposition surface of the target substrate, and the first sputtering target segment may be disposed closer to the shield than the second sputtering target segment.

In an embodiment, the sputtering material may include zinc (Zn), and a composition ratio of zinc (Zn) included in the first sputtering target segment may be higher than a composition ratio of zinc (Zn) included in the second sputtering target segment.

In an embodiment, the composition ratio of zinc (Zn) included in the first sputtering target segment may be in a range of about 4% to about 7% higher than the composition ratio of zinc (Zn) included in the second sputtering target segment.

In an embodiment, the sputtering material may further include indium (In) and gallium (Ga), and a composition ratio of indium (In) and gallium (Ga) included in the first sputtering target segment may be lower than a composition ratio of indium (In) and gallium (Ga) included in the second sputtering target segment.

In an embodiment, a composition ratio of indium (In) included in the first sputtering target segment may be in a range of about 2% to about 5% lower than a composition ratio of indium (In) included in the second sputtering target segment.

In an embodiment, a composition ratio of gallium (Ga) included in the first sputtering target segment may be in a range of about 2% to about 5% lower than a composition ratio of gallium (Ga) included in the second sputtering target segment.

In an embodiment, the first portion may include an edge portion of the sputtering target, and the second portion may include a central portion of the sputtering target.

In an embodiment, the first portion may be disposed at edge portions of the sputtering target in a first direction.

In an embodiment, the sputtering target may include a plurality of first sputtering target segments disposed in edge portions of the sputtering target in the first direction, and a plurality of second sputtering target segments disposed between the plurality of first sputtering target segments.

In an embodiment, the target substrate may be a manufacturing substrate for manufacturing a plurality of display panels.

In an embodiment, the sputtering target may include an oxide semiconductor material for forming oxide transistors of the plurality of display panels.

In an embodiment, the sputtering material may include indium (In), gallium (Ga), and zinc (Zn), and a thin film deposited on the target substrate using the sputtering target may include indium-gallium-zinc oxide (IGZO).

According to an aspect of the disclosure, there is provided a sputtering target including, a first sputtering target segment disposed in a first portion and including a sputtering material, and a second sputtering target segment disposed in a second portion and including the sputtering material, wherein a composition ratio of the sputtering material in the first sputtering target segment may be different from a composition ratio of the sputtering material in the second sputtering target segment.

In an embodiment, the sputtering material may include indium (In), gallium (Ga), and zinc (Zn), and a composition ratio of zinc (Zn) included in the first sputtering target segment may be higher than a composition ratio of zinc (Zn) included in the second sputtering target segment.

In an embodiment, a composition ratio of indium (In) and gallium (Ga) included in the first sputtering target segment may be lower than a composition ratio of indium (In) and gallium (Ga) included in the second sputtering target segment.

In an embodiment, the first portion may include an edge portion of the sputtering target, and the second portion may include a central portion of the sputtering target.

According to an aspect of the disclosure, there is provided a method for manufacturing a display device, including, preparing a manufacturing substrate, forming a thin film including a sputtering material of the sputtering target on the manufacturing substrate, using a sputtering target including a first sputtering target segment and a second sputtering target segment disposed on different portions of the manufacturing substrate, and forming thin film transistors on the manufacturing substrate using the thin film, wherein a composition ratio of the sputtering material in the first sputtering target segment may be different from a composition ratio of the sputtering material in the second sputtering target segment.

In an embodiment, the sputtering target may include indium (In), gallium (Ga), and zinc (Zn), and the thin film may include indium-gallium-zinc oxide (IGZO).

In an embodiment, a composition ratio of zinc (Zn) included in the first sputtering target segment may be higher than a composition ratio of zinc (Zn) included in the second sputtering target segment, and a composition ratio of indium (In) and gallium (Ga) included in the first sputtering target segment may be lower than a composition ratio of indium (In) and gallium (Ga) included in the second sputtering target segment.

The sputtering target according to embodiments may include a first sputtering target segment disposed in a first portion and a second sputtering target segment disposed in a second portion, and composition ratios of the sputtering material in the first sputtering target segment and the second sputtering target segment may be different from each other. In some embodiments, the composition ratio of the sputtering material in the first sputtering target segment and the second sputtering target segment may be adjusted or differentiated to increase the uniformity of the thin film to be manufactured using the sputtering target.

In accordance with the sputtering target, the sputtering apparatus including the sputtering target, and the method for manufacturing a display device using the sputtering target according to embodiments, the uniformity of the thin film formed on the target substrate may be improved. Accordingly, it is possible to increase the manufacturing efficiency of a semiconductor device, e.g., a display device, manufactured using the thin film and reduce the manufacturing cost.

However, effects according to the embodiments of the disclosure are not limited to those examples above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view showing a sputtering apparatus according to an embodiment;

FIG. 2 is a schematic plan view showing a sputtering target according to an embodiment;

FIG. 3 is a schematic plan view showing a thin film deposited on a target substrate using the sputtering target of FIG. 2;

FIG. 4 is a graph showing an atomic ratio of each element according to a position on the thin film of FIG. 3;

FIG. 5 is a schematic plan view showing the sputtering target according to an embodiment;

FIG. 6 is a schematic plan view showing a thin film deposited on the target substrate using the sputtering target of FIG. 5;

FIG. 7 is a schematic cross-sectional view showing a sputtering apparatus according to an embodiment;

FIG. 8 is a schematic perspective view showing the sputtering target according to an embodiment;

FIG. 9 is a flowchart illustrating a method for forming a thin film according to an embodiment;

FIG. 10 is a schematic plan view illustrating a display device according to an embodiment;

FIG. 11 is a schematic plan view illustrating a display panel of FIG. 10;

FIG. 12 is a schematic cross-sectional view illustrating the display panel according to an embodiment; and

FIG. 13 is a flowchart illustrating a method for manufacturing the display device according to an embodiment.

### DETAILED DESCRIPTION OF THE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that in case that an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

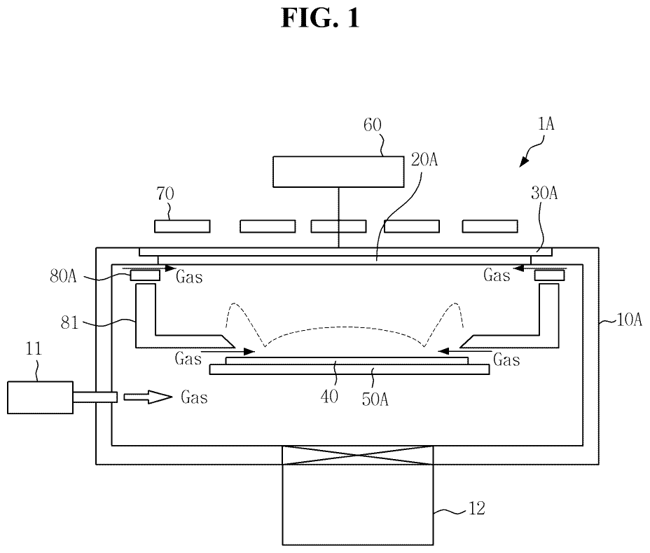

FIG. 1 is a schematic cross-sectional view showing a sputtering apparatus 1A according to an embodiment. For example, FIG. 1 shows the sputtering apparatus 1A with a sputtering target 20A and a target substrate 40 mounted. Although FIG. 1 shows an embodiment in which the sputtering apparatus 1A is a cluster-type stationary film forming apparatus, the type or structure of the sputtering apparatus 1A is not limited thereto. The sputtering apparatus 1A may also be referred to as a thin film deposition apparatus.

Referring to FIG. 1, the sputtering apparatus 1A according to an embodiment may include a chamber 10A that provides a sputtering space. In FIG. 1, the chamber 10A is schematically illustrated with respect to the wall surface of the chamber 10A. The chamber 10A may be equipped with a gas injector 11 and an intake system 12 (e.g., a vacuum pump).

The gas injector 11 may supply a sputter gas, such as argon (Ar) gas, into the chamber 10A. The gas injector 11 may be a mass flow controller (MFC), but embodiments are not limited thereto. In an embodiment, in case that a reaction gas is required for the deposition of a thin film, the gas injector 11 may further supply the reaction gas in addition to the sputter gas. In an embodiment, the reaction gas may be oxygen (O₂) gas, but embodiments are not limited thereto.

The intake system 12 may include a device for vacuuming the inside of the chamber 10A. For example, the intake system 12 may include a vacuum pump (e.g., a cryogenic (cryo) pump) or a turbo molecular pump (TMP).

The sputtering apparatus 1A may further include a backing plate 30A coupled to the sputtering target 20A, and a susceptor 50A (or a support plate) coupled to the target substrate 40.

The backing plate 30A may support the sputtering target 20A. For example, the backing plate 30A may be positioned on the rear surface of the sputtering target 20A and may stably fix and support the sputtering target 20A. In an embodiment, the backing plate 30A may provide a cooling function. In another example, a cooling device may be provided around the backing plate 30A. Accordingly, heat generated from the sputtering target 20A may be absorbed or dispersed, and the stability of the sputtering target 20A may be secured (or ensured).

The sputtering target 20A may be disposed on a surface of the backing plate 30A facing the susceptor 50A. The sputtering target 20A may include a sputtering material to be used for the deposition of the thin film. For example, in case that an indium gallium-zinc oxide (IGZO) thin film is to be formed on the target substrate 40, the sputtering target 20A may include a sputtering material (e.g., indium-gallium-zinc oxide (IGZO)) including indium (In), gallium (Ga), and zinc (Zn). In an embodiment, oxygen (O₂) gas may be used as the reaction gas.

The susceptor 50A may support the target substrate 40. The susceptor 50A may provide a heating function. By using the heating function of the susceptor 50A to appropriately control the temperature of the target substrate 40, desired thin film characteristics may be achieved.

The target substrate 40 may be disposed on the susceptor 50A. The target substrate 40 may be an object on which the thin film is to be deposited. For example, the target substrate 40 may be a target surface on which particles from the sputtering target 20A are deposited during a thin film deposition process by a sputtering method. The target substrate 40 may be disposed in the chamber 10A to face the sputtering target 20A at a position spaced apart from the sputtering target 20A. For example, the target substrate 40 may be disposed on the susceptor 50A such that the surface, on which the thin film is to be formed, may face the sputtering target 20A.

The sputtering apparatus 1A may further include a power supply 60 connected to the backing plate 30A, and a magnet 70 disposed around the backing plate 30A.

The power supply 60 may apply a power voltage (e.g., a negative voltage) to the backing plate 30A. Accordingly, high-energy plasma may be generated in a plasma space (e.g., a space surrounded by the sputtering target 20A, the target substrate 40, a shield 80A, and a mask 81) formed between the sputtering target 20A and the target substrate 40 and may collide with (or impact) the sputtering target 20A. Accordingly, particles ejected from the sputtering target 20A may collide with (or impact) the target substrate 40 to form the thin film. In an embodiment, the power supply 60 may be a direct current (DC) type, alternating current (AC) type, or radio frequency (RF) type power supply, but embodiments are not limited thereto.

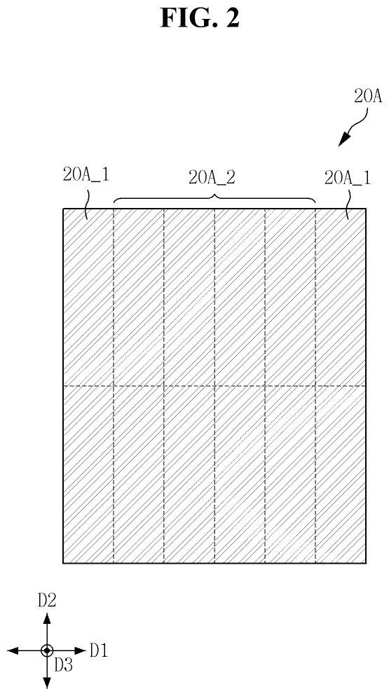

The magnet 70 may be positioned around the sputtering target 20A to form a magnetic field. In an embodiment, at least two magnets 70 arranged along a direction (e.g., a first direction D1 of FIG. 2) may be disposed around the sputtering target 20A, and each magnet 70 may have a bar shape extending in a direction (e.g., a second direction D2 of FIG. 2). The shape, size, number, or arrangement structure of the magnets 70 may vary according to embodiments. The trajectory of the particles ejected from the sputtering target 20A and the characteristics of the thin film formed on the target substrate 40 may be controlled by the magnetic field of the magnet 70. In an embodiment, the magnet 70 may be coupled to a moving device, and accordingly, the position of the magnet 70 may be appropriately adjusted or changed.

The sputtering apparatus 1A may further include the shield 80A (e.g., a ground shield) and the mask 81 disposed in the chamber 10A. The shield 80A and the mask 81 may be disposed between the sputtering target 20A and the target substrate 40, and may expose a thin film deposition surface (or a thin film deposition area) of the target substrate 40. The wall surfaces of the shield 80A, the mask 81, and the chamber 10A may be grounded or connected to an electrical ground.

The shield 80A may be disposed around the sputtering target 20A. For example, the shield 80A may have a shape surrounding the sputtering target 20A in plan view (e.g., when viewed on an XY plane defined by the first direction D1 and the second direction D2 of FIG. 2), and may include an opening corresponding to the sputtering target 20A. In an example, the shield 80A may have a frame shape surrounding the sputtering target 20A in plan view.

The mask 81 may be disposed around the target substrate 40, and may surround the thin film deposition area of the target substrate 40. For example, the mask 81 may surround the thin film deposition area of the target substrate 40 in plan view, and may include an opening corresponding to the thin film deposition area. In an embodiment, the mask 81 may have a frame shape surrounding the thin film deposition area while overlapping the edge portion of the target substrate 40.

The mask 81 may be connected to the shield 80A. The shield 80A and the mask 81 may be regarded as separate individual components, or as a single interconnected component.

The shield 80A and the mask 81 may provide an electrically stable environment to prevent electromagnetic interference that occurs during a sputtering process. For example, the shield 80A and the mask 81 may limit a space in which the particles ejected from the sputtering target 20A are dispersed, and may prevent contamination of the chamber 10A. The plasma space, in which plasma is generated, may be defined by the sputtering target 20A, the target substrate 40, the shield 80A, and the mask 81.

In a state where the sputtering target 20A and target substrate 40 are mounted in the chamber 10A, after creating a vacuum environment and injecting a sputter gas or the like, a power voltage may be applied to the backing plate 30A to generate plasma. Plasma may be relatively uniformly distributed in the plasma space between the sputtering target 20A and the target substrate 40. However, in the vicinity of the mask 81, the density of the plasma may significantly increase due to the formation of a stronger electric field than in other areas. For example, as illustrated by a dashed line in FIG. 1 (e.g., a dashed line schematically representing the plasma density around the target substrate 40), the plasma density may increase significantly around the end portion of the mask 81, thereby leading to plasma non-uniformity. The plasma non-uniformity may affect the characteristics of the thin film formed on the target substrate 40.

FIG. 2 is a schematic plan view showing the sputtering target 20A according to an embodiment. For example, FIG. 2 shows the sputtering target 20A that is mounted on the sputtering apparatus 1A of FIG. 1.

The first direction D1, the second direction D2, and a third direction D3 are illustrated in FIG. 2. In an embodiment, the sputtering target 20A may be manufactured in a plate shape, and the first direction D1, the second direction D2, and the third direction D3 of FIG. 2 may correspond to a horizontal direction (e.g., X-axis direction), a vertical direction (e.g., Y-axis direction), and a thickness direction (e.g., Z-axis direction) of the sputtering target 20A, respectively.

Referring to FIGS. 1 and 2, the sputtering target 20A may be formed of sputtering target segments 20A_1 and 20A_2 (or segmented regions). In an embodiment, the sputtering target segments 20A_1 and 20A_2 having a size smaller than the target substrate 40 may be individually manufactured, and then the sputtering target segments 20A_1 and 20A_2 may be combined or assembled to form the sputtering target 20A having a size corresponding to the target substrate 40. For example, the plate-shaped sputtering target 20A having a size greater than or equal to the target substrate 40 may be manufactured by combining the plate-shaped sputtering target segments 20A_1 and 20A_2 having a size smaller than the target substrate 40.

In an embodiment, the sputtering target segments 20A_1 and 20A_2 may include substantially the same sputtering material, and the composition ratios of the sputtering material included in the sputtering target segments 20A_1 and 20A_2 may be substantially the same. In an embodiment, the sputtering target segments 20A_1 and 20A_2 may include at least one of indium (In), gallium (Ga), or zinc (Zn). For example, the sputtering target segments 20A_1 and 20A_2 may include indium-gallium-zinc oxide (IGZO), and the composition ratios of indium (In), gallium (Ga), and zinc (Zn) included in the sputtering target segments 20A_1 and 20A_2 may be uniform. For example, the composition ratio of indium (In), gallium (Ga), and zinc (Zn) of first sputtering target segments 20A_1 positioned at edge portions (e.g., opposite edge portions) of the sputtering target 20A in the first direction D1 may be substantially the same as the composition ratio of indium (In), gallium (Ga), and zinc (Zn) of second sputtering target segments 20A_2 positioned at other portions of the sputtering target 20A.

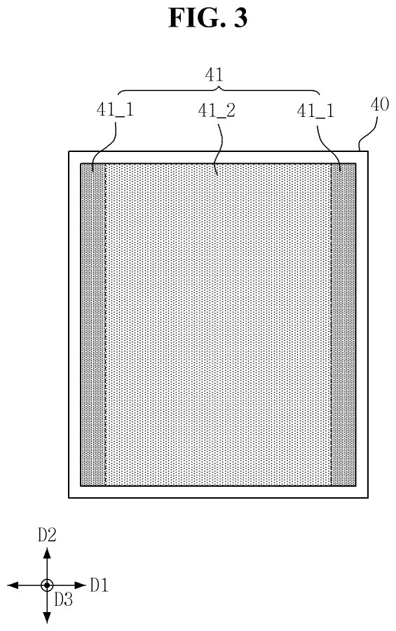

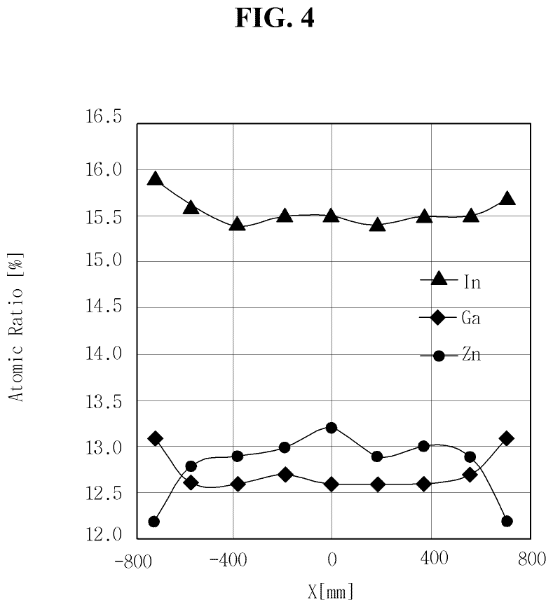

FIG. 3 is a schematic plan view showing a thin film 41 deposited on the target substrate 40 using the sputtering target 20A of FIG. 2. FIG. 4 is a graph showing an atomic ratio of each element according to a position on the thin film 41 of FIG. 3. For example, FIG. 4 shows the atomic ratios of indium (In), gallium (Ga), and zinc (Zn) according to an X coordinate corresponding to a position in the first direction D1.

The first direction D1, the second direction D2, and the third direction D3 are illustrated in FIG. 3. In an embodiment, the target substrate 40 may be a plate-shaped substrate, and the first direction D1, the second direction D2, and the third direction D3 may correspond to the horizontal direction (e.g., X-axis direction), the vertical direction (e.g., Y-axis direction), and the thickness direction (e.g., Z-axis direction) of the target substrate 40, respectively.

Referring to FIGS. 3 and 4 in addition to FIGS. 1 and 2, due to the plasma non-uniformity (e.g., plasma density deviation) occurring during the deposition of the thin film 41, the composition ratio of the material constituting the thin film 41 in an edge portion 41_1 of the thin film 41 in the first direction D1 may be significantly different from that in the other portion of the thin film 41. For example, in case that the thin film 41 deposited on the target substrate 40 includes indium-gallium-zinc oxide (IGZO), the composition ratio of a material, e.g., zinc (Zn), having a relatively weak bonding energy may decrease significantly in the edge portion 41_1 of the thin film 41 compared to the other portion (or central portion) 41_2 of the thin film 41, while the composition ratio of indium (In) and gallium (Ga) may increase. In an example, zinc (Zn) having a weak bonding energy may volatilize more readily than indium (In) and gallium (Ga) in the edge portion 41_1 of the thin film 41. Accordingly, the composition ratio of the material constituting the thin film 41 in the edge portion 41_1 of the thin film 41 may be different (e.g., to an extent beyond an allowable range) from the composition ratio of the material constituting the thin film 41 in the other portion (or central portion) 41_2. Due to this composition ratio deviation, the edge portion 41_1 of the thin film 41 may have different characteristics from the other portion 41_2 (or central portion) of the thin film 41.

In an embodiment, the target substrate 40 may be a manufacturing substrate for manufacturing a semiconductor device. For example, the target substrate 40 may be a manufacturing substrate (e.g., a mother substrate) for simultaneously manufacturing display panels, and may include cell areas (or unit areas) corresponding to the above display panels. Each cell area may include pixel areas. In another example, the target substrate 40 may be a manufacturing substrate for manufacturing a display panel, and may include pixel areas (or unit areas). In an embodiment, the sputtering target 20A may include an oxide semiconductor material for forming oxide transistors of the display panels.

In case that the semiconductor device, e.g., the display panels (e.g., a backplane or a thin film transistor substrate of each of the display panels), is manufactured using the target substrate 40 on which the thin film 41 has different characteristics for each portion, the thin film transistor substrate of the display panel formed in the cell area positioned at the edge portion of the target substrate 40 may exhibit different characteristics from the thin film transistor substrate of the display panel formed in the cell area positioned in other portions of the target substrate 40.

For example, due to the characteristic deviation of the thin film 41 (e.g., indium-gallium-zinc oxide (IGZO) thin film), a characteristic deviation (e.g., carrier concentration deviation) of the oxide transistors formed from the thin film 41 may occur. As a result, a characteristic deviation between the display panels may occur according to the position on the target substrate 40. Accordingly, the yield rate or utilization rate of the target substrate 40 may decrease, and the yield of the semiconductor device, e.g., the display device, manufactured from the target substrate 40 may also decrease.

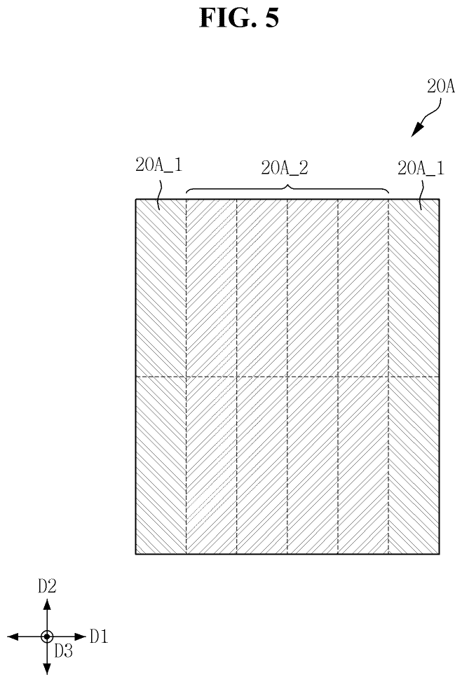

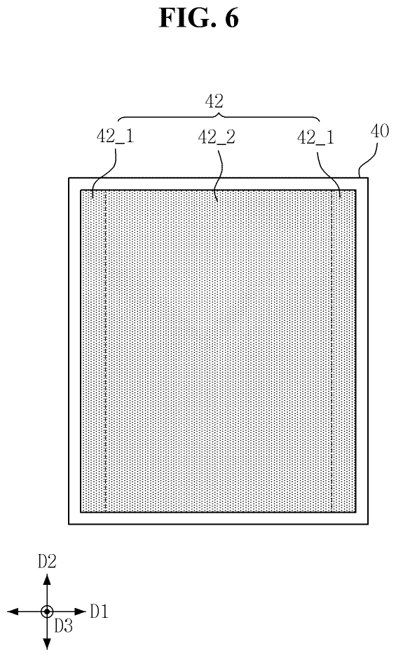

FIG. 5 is a schematic plan view showing the sputtering target 20A according to an embodiment. For example, FIG. 5 shows the sputtering target 20A that is mounted on the sputtering apparatus 1A of FIG. 1, according to an embodiment different from the embodiment of FIG. 2. FIG. 6 is a schematic plan view showing a thin film 42 deposited on the target substrate 40 using the sputtering target 20A of FIG. 5.

Referring to FIGS. 5 and 6, in addition to FIGS. 1 to 4, the sputtering target 20A according to an embodiment may include the sputtering target segments 20A_1 and 20A_2 (or segmented regions). For example, the sputtering target 20A may include at least one first sputtering target segment 20A_1 disposed in a first portion and at least one second sputtering target segment 20A_2 disposed in a second portion.

In an embodiment, the first portion may include an edge portion of the sputtering target 20A, and the second portion may include a central portion of the sputtering target 20A. For example, the first portion may be positioned at edge portions (e.g., opposite edge portions) of the sputtering target 20A in the first direction D1, and the second portion may be positioned at the central portion of the sputtering target 20A in the first direction D1. The sputtering target 20A may include the first sputtering target segments 20A_1 dividedly disposed in edge portions (e.g., opposite edge portions) of the sputtering target 20A, and at least one second sputtering target segment 20A_2 disposed between the first sputtering target segments 20A_1. In an embodiment, the second portion of the sputtering target 20A may have a size larger than the first portion of the sputtering target 20A, and the second sputtering target segments 20A_2 may be disposed in the second portion.

In an embodiment, the sputtering target segments 20A_1 and 20A_2 may be manufactured to be substantially the same or similar in size. For example, the sputtering target segments 20A_1 and 20A_2 may be individually sintered to a predetermined size, and then the sputtering target segments 20A_1 and 20A_2 may be combined, assembled, or arranged to form the sputtering target 20A. However, the embodiments are not limited thereto. For example, the sputtering target 20A may be manufactured by combining, assembling, or arranging the sputtering target segments 20A_1 and 20A_2 of different sizes.

In an embodiment, the sputtering target segments 20A_1 and 20A_2 may include substantially the same sputtering material, but the composition ratio of the sputtering material included in the first sputtering target segment 20A_1 disposed in the first portion (e.g., the edge portion of the sputtering target 20A) may be different from the composition ratio of the sputtering material included in the second sputtering target segment 20A_2 disposed in the second portion (e.g., the central portion of the sputtering target 20A).

In an embodiment, each of the first sputtering target segments 20A_1 may be disposed in the edge portion (e.g., a left edge portion or a right edge portion) of the sputtering target 20A in the first direction D1. In a state where the sputtering target 20A is mounted on the sputtering apparatus 1A, the first sputtering target segment 20A_1 may be disposed closer to the shield 80A (or the mask 81) than the second sputtering target segment 20A_2.

The composition ratio of the sputtering material forming each first sputtering target segment 20A_1 may be different from the composition ratio of the sputtering material forming each second sputtering target segment 20A_2. In an embodiment, the sputtering target segments 20A_1 and 20A_2 may include at least one of indium (In), gallium (Ga), or zinc (Zn). For example, the sputtering target segments 20A_1 and 20A_2 may include indium-gallium-zinc oxide (IGZO). The composition ratio of at least one of indium (In), gallium (Ga), and zinc (Zn) included in the first sputtering target segment 20A_1 may be different from the composition ratio of at least one of indium (In), gallium (Ga), and zinc (Zn) included in the second sputtering target segment 20A_2.

For example, the composition ratio of zinc (Zn) having a relatively weak bonding energy may be higher in the first sputtering target segment 20A_1 than in the second sputtering target segment 20A_2. In an embodiment, the composition ratio of zinc (Zn) included in the first sputtering target segment 20A_1 may be about 4% to about 7% higher than the composition ratio of zinc (Zn) included in the second sputtering target segment 20A_2. In an embodiment, the difference in the composition ratio of zinc (Zn) between the first sputtering target segment 20A_1 and the second sputtering target segment 20A_2 may be a value for preventing or reducing a deviation in the composition ratio of zinc (Zn) in the thin film 42 manufactured using the sputtering target 20A. For example, the difference in the composition ratio of zinc (Zn) between the first sputtering target segment 20A_1 and the second sputtering target segment 20A_2 may be set to a value that resolves or mitigates the non-uniformity in the composition ratio of zinc (Zn) shown in FIG. 4.

The composition ratio of other elements, e.g., indium (In) and gallium (Ga), included in the sputtering material may be lower in the first sputtering target segment 20A_1 than in the second sputtering target segment 20A_2. In an embodiment, the composition ratio of indium (In) included in the first sputtering target segment 20A_1 may be about 2% to about 5% lower than the composition ratio of indium (In) included in the second sputtering target segment 20A_2. In an embodiment, the composition ratio of gallium (Ga) included in the first sputtering target segment 20A_1 may be about 2% to about 5% lower than the composition ratio of gallium (Ga) included in the second sputtering target segment 20A_2. In an embodiment, the difference in the composition ratio of indium (In) and gallium (Ga) between the first sputtering target segment 20A_1 and the second sputtering target segment 20A_2 may be a value for preventing or reducing a deviation in the composition ratio of indium (In) and gallium (Ga) in the thin film 42 manufactured using the sputtering target 20A. For example, the difference in the composition ratio of indium (In) and gallium (Ga) between the first sputtering target segment 20A_1 and the second sputtering target segment 20A_2 may be set to a value that resolves or mitigates the non-uniformity in the composition ratio of indium (In) and gallium (Ga) shown in FIG. 4.

The difference in the composition ratio of the sputtering material between the first sputtering target segment 20A_1 and the second sputtering target segment 20A_2 is not limited to the embodiments. For example, the composition ratio of the material included in the sputtering target segments 20A_1 and 20A_2 may be experimentally determined as a value that increases the uniformity of the thin film 42 to be finally deposited.

In an embodiment, the composition ratio of the material included in the first sputtering target segments 20A_1 and the second sputtering target segments 20A_2 constituting the sputtering target 20A may be appropriately adjusted or differentiated in order to predict the non-uniformity of the thin film 42 to be formed on the target substrate 40 and to resolve or mitigate the non-uniformity of the thin film 42. For example, in consideration of the location (or position) where a characteristic deviation is expected to occur in the thin film 42 and the aspect or degree of the characteristic deviation, the composition ratio of the material included in the sputtering target 20A may be adjusted or changed for each portion to facilitate more uniform deposition of the thin film 42 on the target substrate 40.

In an example, by predicting the non-uniformity of the thin film 42 due to plasma non-uniformity or other factors, the composition ratio of the sputtering material included in the first sputtering target segments 20A_1 and the second sputtering target segments 20A_2 may be appropriately adjusted or differentiated. Accordingly, it is possible to increase the uniformity of the deposited thin film 42 using the sputtering target 20A. In an example, the thin film 42 may be deposited using the sputtering target 20A in which the composition ratio of zinc (Zn) is increased and the composition ratio of indium (In) and gallium (Ga) is decreased in the first sputtering target segments 20A_1 compared to the second sputtering target segments 20A_2, and accordingly, the deposited thin film 42 may exhibit uniform characteristics overall. For example, in the case of the thin film 42 deposited using the sputtering target 20A in which the composition ratio of the material included in the first sputtering target segments 20A_1 has been adjusted to form the thin film 42 having uniform characteristics, the deviation in the composition ratio of the sputtering material in an edge portion 42_1 and the composition ratio of the sputtering material in the other portion (or central portion) 42_2 may be prevented or reduced.

Therefore, in case that the thin film 42 is deposited using the sputtering target 20A in which the composition ratio of the material in the first sputtering target segments 20A_1 has been adjusted as in the embodiment of FIG. 5, the thin film 42 with overall uniform characteristics may be formed on the target substrate 40. Accordingly, the characteristic deviation of the semiconductor device, e.g., the display panels (e.g., the backplane or the thin film transistor substrate of each of the display panels), manufactured using the thin film 42 may be prevented or reduced. As a result, it is possible to increase the glass efficiency of the target substrate 40 (e.g., the ratio of an actual area of the target substrate 40 that is used or manufactured into the semiconductor device to the total area of the target substrate 40), and improve the yield of the semiconductor device, e.g., the display device, manufactured from the target substrate 40.

FIGS. 5 and 6 illustrate an embodiment in which the composition ratio of the first sputtering target segments 20A_1 positioned at end portions (e.g., opposite end portions) adjacent to the mask 81 is adjusted or changed in order to resolve the non-uniformity of the thin film 42 due to the plasma non-uniformity caused by the position of the mask 81 (or the shield 80A) described with reference to FIGS. 1 to 4, but embodiments are not limited thereto. For example, in case that the non-uniformity of the thin film deposition occurs due to other factors, in order to resolve the non-uniformity of the thin film deposition due to the above other factors, the uniform thin film 42 may be deposited using the sputtering target 20A in which the composition ratio of the sputtering material constituting the sputtering target segments 20A_1 and 20A_2 has been adjusted or changed based on the location (or position) and degree to which the non-uniformity of the thin film 42 occurs.

In FIGS. 2 and 5, the sputtering target 20A is shown to include a total of twelve sputtering target segments 20A_1 and 20A_2, with six sputtering target segments 20A_1 and 20A_2 arranged along the first direction D1 and two sputtering target segments 20A_1 and 20A_2 arranged along the second direction D2, but embodiments are not limited thereto. For example, the number, size, or arrangement structure of the sputtering target segments 20A_1 and 20A_2 constituting the sputtering target 20A may be variously changed according to embodiments. For example, it is not necessary for the sputtering target 20A to be composed of the individually formed sputtering target segments 20A_1 and 20A_2. For example, the sputtering target 20A may be sintered or manufactured as a single target, and the composition ratio of the sputtering material included in a portion of the sputtering target 20A may be different from the composition ratio of the sputtering material included in the other portion of the sputtering target 20A. For example, in case that the thin film 42 can be divided into two areas based on the portion where the non-uniformity of the thin film 42 may occur, the sputtering target 20A may be divided into two groups of sputtering target segments 20A_1 and 20A_2 or two areas to differentiate the composition ratio of the sputtering material.

For example, in embodiments, a material (e.g., indium-gallium-zinc oxide (IGZO)) including indium (In), gallium (Ga), and zinc (Zn) is an example of the sputtering material, but the sputtering material that is applied to the embodiments is not limited thereto. For example, the sputtering material may be variously changed according to the type, material, or the like of the thin film 42 to be formed. For example, in case that the uniformity of the thin film 42 decreases due to various factors such as a sputtering environment or a bonding energy of elements forming the sputtering material, the composition ratio of the sputtering material may be appropriately adjusted or changed for each portion to increase the uniformity of the thin film 42.

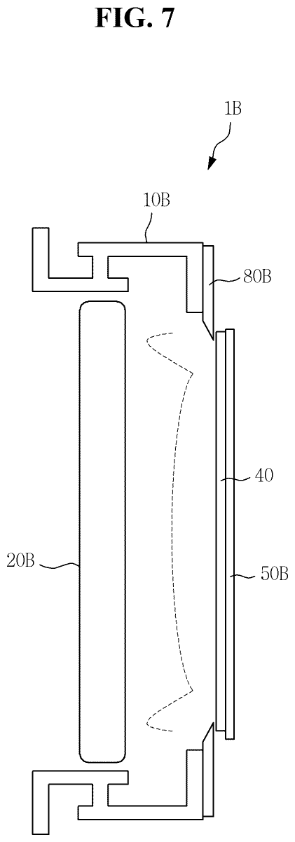

FIG. 7 is a schematic cross-sectional view showing a sputtering apparatus 1B according to an embodiment. For example, FIG. 7 schematically shows the sputtering apparatus 1B equipped with a sputtering target 20B and the target substrate 40. FIG. 7 shows an embodiment in which the sputtering apparatus 1B is an inline-type movable film forming apparatus, but the type or structure of the sputtering apparatus 1B according to embodiments is not limited thereto.

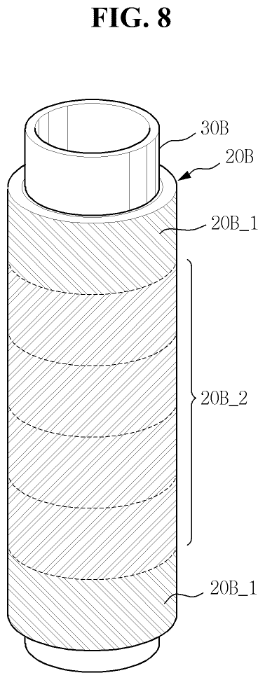

FIG. 8 is a schematic perspective view showing the sputtering target 20B according to an embodiment. For example, FIG. 8 shows a cylindrical sputtering target 20B as an example of the sputtering target 20B that is mounted on the sputtering apparatus 1B of FIG. 7. For example, FIG. 8 shows a cylindrical backing plate 30B as an example of a backing plate 30B that is coupled to the cylindrical sputtering target 20B.

Referring to FIGS. 7 and 8, the sputtering apparatus 1B according to an embodiment may include a chamber 10B that provides a sputtering space. In FIG. 7, the chamber 10B is schematically illustrated with respect to the wall surface of the chamber 10B.

The sputtering apparatus 1B may include the sputtering target 20B, the target substrate 40, and a shield 80B (e.g., a ground shield) installed or mounted on the chamber 10B. The sputtering apparatus 1B may further include additional components (e.g., a power supply, a gas injector, and the like) in addition to the configuration shown in FIG. 7.

The target substrate 40 may be transferred by a transferring device and may be erected to face the sputtering target 20B. The target substrate 40 may be coupled to a susceptor 50B (or a support plate). The shield 80B may provide an electrically stable environment and may also function as a mask.

In an embodiment, the sputtering target 20B may be manufactured in a cylindrical shape or the like, and may have an open top and bottom shape (or open top and bottom ends). In an embodiment, the sputtering target 20B may be coupled to the backing plate 30B (or an electrode) having a shape corresponding to the sputtering target 20B. For example, the sputtering target 20B may be coupled to the cylindrical backing plate 30B. The sputtering target 20B and/or the backing plate 30B may be coupled to a rotation device to rotate. For example, as the sputtering target 20B rotates, the thin film deposition process may proceed, and the particles ejected from the sputtering target 20B may be deposited on the target substrate 40.

In an embodiment, the thin film 42 may be deposited on the target substrate 40 using the single sputtering target 20B, or the thin film 42 may be deposited on the target substrate 40 using the sputtering targets 20B. For example, the number of the sputtering targets 20B used in the thin film deposition process may vary according to embodiments.

In an embodiment, the composition ratio of the material forming the sputtering target 20B may partially vary according to the location (or position) in the sputtering target 20B. For example, the sputtering target 20B may include first sputtering target segments 20B_1 (or first segmented regions) overlapping the edge portion of the target substrate 40 and the shield 80B, and the second sputtering target segments 20B_2 (or second segmented regions) positioned in the remaining portion, and the composition ratio of the material included in the first sputtering target segments 20B_1 may be different from the composition ratio of the material included in the second sputtering target segments 20B_2.

For example, as in the embodiment of FIGS. 5 and 6, the composition ratio of the material included in the first sputtering target segments 20B_1 and the second sputtering target segments 20B_2 may be appropriately adjusted or differentiated to resolve or mitigate the non-uniformity of the thin film 42 to be formed on the target substrate 40. Accordingly, as in the embodiment of FIG. 6, the thin film 42 having uniform characteristics may be formed on the target substrate 40.

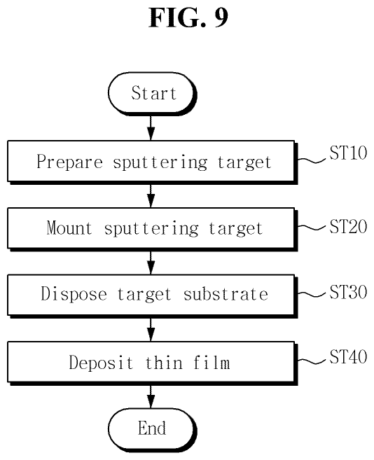

FIG. 9 is a flowchart illustrating a method for forming a thin film according to an embodiment.

Referring to FIGS. 1 to 9, the sputtering target 20A and/or 20B may be prepared (step ST10). For example, the sputtering target 20A and/or 20B including a sputtering material corresponding to the thin film 42 to be formed may be prepared. In an embodiment, the sputtering target 20A and/or 20B including at least one first sputtering target segment 20A_1 and/or 20B_1 (or first segmented region) disposed in the first portion (e.g., a portion including the edge in the first direction D1) and at least one second sputtering target segment 20A_2 and/or 20B_2 (or second segmented region) disposed in the second portion (e.g., a portion including the center in the first direction D1) may be prepared so as to deposit the uniform thin film 42 on the target substrate 40. For example, the sputtering target 20A and/or 20B may include the first sputtering target segment 20A_1 and/or 20B_1 and the second sputtering target segment 20A_2 and/or 20B_2 with different composition ratios of the sputtering material as in the embodiment of FIG. 5 or FIG. 8. In an example, the sputtering target 20A and/or 20B may include indium (In), gallium (Ga), and zinc (Zn), and the composition ratio of indium (In), gallium (Ga), and zinc (Zn) of the first sputtering target segment 20A_1 and/or 20B_1 may be different from the composition ratio of indium (In), gallium (Ga), and zinc (Zn) of the second sputtering target segment 20A_2 and/or 20B_2.

Thereafter, the sputtering target 20A and/or 20B may be mounted in the chamber 10A, 10B (step ST20). For example, the prepared sputtering target 20A and/or 20B may be coupled to the backing plate 30A, 30B and mounted in the chamber 10A and/or 10B.

Thereafter, the target substrate 40 may be disposed to face the sputtering target 20A and/or 20B (step ST30). In an embodiment, the edge portion of the target substrate 40 may overlap at least one of the mask 81 and the shield 80A and/or 80B. For example, at least one of the mask 81 and the shield 80A and/or 80B may be disposed between the target substrate 40 and the sputtering target 20A and/or 20B, and the edge portion of the target substrate 40 may be covered by at least one of the mask 81 and the shield 80A and/or 80B. In an embodiment, the target substrate 40 may be a manufacturing substrate for simultaneously manufacturing display panels. For example, the target substrate 40 may be a manufacturing substrate (e.g., a mother substrate) of a display device including unit areas in which respective display panels are to be formed.

Thereafter, the thin film 42 may be deposited on the target substrate 40 using the sputtering target 20A and/or 20B (step ST40). For example, after creating a vacuum environment in the chamber 10A, 10B and injecting a gas including a sputter gas or the like, a power voltage may be applied to the backing plate 30A, 30B. Accordingly, the thin film 42 including the sputtering material included in the sputtering target 20A and/or 20B may be deposited on the target substrate 40. In an embodiment, the sputtering target 20A and/or 20B may include indium (In), gallium (Ga), and zinc (Zn). For example, the sputtering target 20A and/or 20B may be made of indium-gallium-zinc oxide (IGZO). Accordingly, the thin film 42 including indium-gallium-zinc oxide (IGZO) may be deposited on the target substrate 40. In an embodiment, the thin film 42 may be used to form the active layers of the oxide transistors provided in each display panel. For example, the thin film 42 may be etched to form the active layers of the oxide transistors in the unit areas in which respective display panels are to be formed.

According to the sputtering targets 20A and 20B in which the composition ratio of the sputtering material has been adjusted for each sputtering target segment 20A_1, 20A_2, 20B_1, and/or 20B_2 or each segmented region as in the embodiments of FIGS. 5 and 8, the sputtering apparatuses 1A and 1B equipped with or using the sputtering targets 20A and 20B, and the thin film forming method using the sputtering targets 20A and 20B, the thin film 42 having uniform characteristics may be formed. For example, by using the sputtering targets 20A and 20B according to embodiments, the thin film 42 with uniform characteristics may be formed over the entire area.

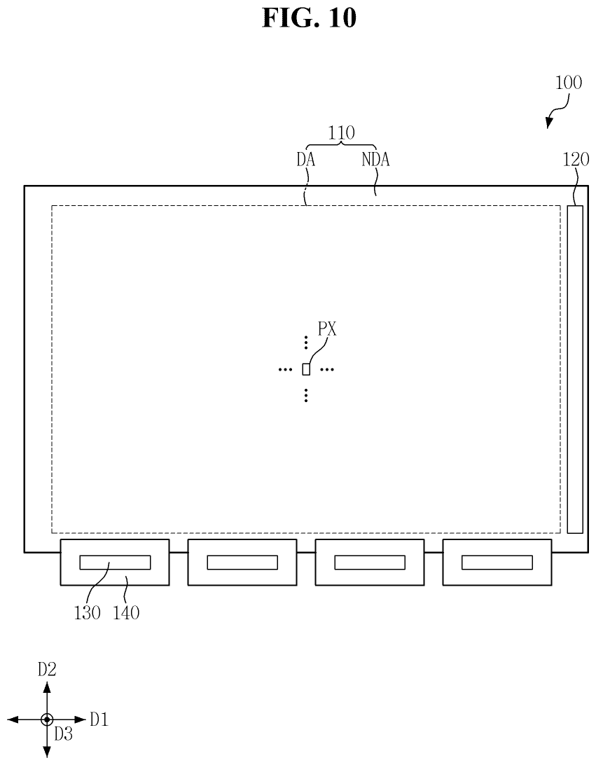

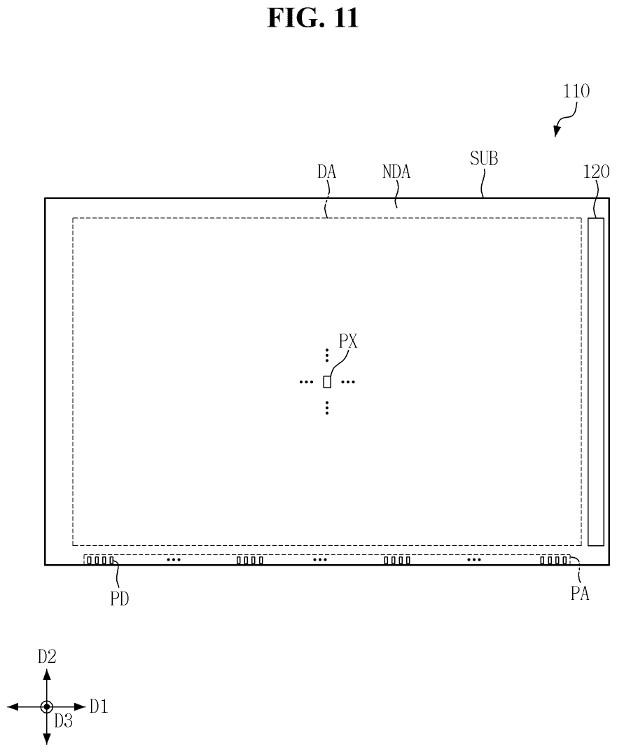

FIG. 10 is a schematic plan view illustrating a display device 100 according to an embodiment. FIG. 11 is a schematic plan view illustrating a display panel 110 of FIG. 10.

Referring to FIGS. 10 and 11, the display device 100, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display including an ultra-small light emitting diode such as a micro or nano light emitting diode (micro LED or nano LED), but embodiments are not limited thereto. For example, the display device 100 may be another type of display device other than a light emitting display device. In the following, embodiments in which the display device 100 is a light emitting display device (e.g., an organic light emitting display device) will be disclosed.

The display device 100 may include the display panel 110 including pixels PX, and a first driver 120 and a second driver 130 that supply driving signals to the pixels PX. The display device 100 may further include additional components. For example, the display device 100 may further include a power supply unit for supplying power voltages to the pixels PX, the first driver 120, and the second driver 130, and a timing controller for controlling the operations of the first driver 120 and the second driver 130.

The display panel 110 may include a display area DA and a non-display area NDA. The display area DA may be an area including the pixels PX to display an image. For example, the display area DA may include pixel areas where the pixels PX are arranged. The non-display area NDA is an area other than the display area DA, and an image may not be displayed in the non-display area NDA. In an embodiment, the non-display area NDA may be positioned around the display area DA and may surround the display area DA.

In FIGS. 1 and 2, a first direction D1, a second direction D2, and a third direction D3 are defined. In an embodiment, the first direction D1 may be the horizontal direction of the display panel 110, and the second direction D2 may be the vertical direction of the display panel 110. The third direction D3 may be a thickness direction of the display panel 110.

In an embodiment, the display panel 110 may have a rectangular shape in plan view. Although FIGS. 1 and 2 illustrate the display panel 110 with a horizontal length longer than a vertical length, the shape of the display panel 110 is not limited thereto. For example, the display panel 110 may have a shape with a vertical length longer than a horizontal length, a square shape, or the like. The display panel 110 may include an angled corner or a rounded corner.

The planar shape of the display panel 110 is not limited to a quadrilateral shape, and may be other shapes. For example, the display panel 110 may have another polygonal shape, a circular shape, an elliptical shape, or another planar shape.

The display panel 110 may be provided as a rigid panel so as not to be substantially transformed, or as a flexible panel that is transformed to be at least partially folded, bent, or rolled. The display panel 110 may be provided to the display device 100 without bending, or may be provided to the display device 100 while being partially bent.

The display panel 110 may include a substrate SUB and the pixels PX disposed on the substrate SUB. The pixels PX may be disposed in the display area DA on the substrate SUB.

The substrate SUB, which is a base member for manufacturing or providing the display panel 110, may form the base surface of the display panel 110. The substrate SUB may include the display area DA and the non-display area NDA around the display area DA.

The display area DA may have various shapes according to embodiments. For example, the display area DA may have a quadrilateral shape, a non-quadrilateral polygonal shape, a circular shape, an elliptical shape, or another shape. In an embodiment, the display area DA may have a shape conforming to the shape of the display panel 110.

The pixels PX may be provided and/or arranged in the display area DA. For example, the display area DA may include pixel areas in which the respective pixels PX are disposed.

In an embodiment, the display device 100 may be a light emitting display device, and each pixel PX may include a light emitting element positioned in each emission area and a pixel circuit connected to the light emitting element. In describing embodiments, the term “connect” may include electrical connection and/or physical connection. Each pixel circuit may include transistors (e.g., transistors including a driving transistor that generates a driving current corresponding to a data signal, and at least one switching transistor) and at least one capacitor (e.g., a capacitor including a storage capacitor).

The non-display area NDA may include a pad area PA where pads PD are disposed. In an embodiment, the non-display area NDA may further include a driving circuit area positioned on at least one side of the display area DA. At least one driver, the pads PD, and/or wires may be disposed in the non-display area NDA.

At least one driver for driving the pixels PX, or a part of the driver may be disposed in the driving circuit area. For example, circuit elements constituting the first driver 120 (e.g., driver transistors and driver capacitors constituting the stage circuits of the first driver 120) may be disposed in the driving circuit area on the substrate SUB. In an embodiment, the circuit elements of the first driver 120 may be formed in the display panel 110 together with the pixels PX. In an embodiment, the driving transistors provided in the first driver 120 may be transistors having a type and/or a structure that are substantially the same as or similar to those of the transistors provided in the pixels PX, and may be formed simultaneously with the transistors of the pixels PX.

The pads PD may be disposed in the pad area PA. At least one circuit board 140 may be disposed and/or bonded on the pad area PA. In an embodiment, circuit boards 140 connected to different pads PD may be disposed on the pad area PA. The pads PD may include signal pads and power pads for transmitting driving signals and power voltages required for driving the pixels PX and/or the first driver 120 into the display panel 110.

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be connected to the pixels PX through respective gate lines. The first driver 120 may supply respective gate signals (e.g., control signals for controlling the driving timing of the pixels PX, including scan signals and/or emission control signals) to the pixels PX. The second driver 130 may be a data driver including source driving circuits, and may be connected to the pixels PX through respective data lines. The second driver 130 may supply respective data signals to the pixels PX.

In an embodiment, at least a portion of the first driver 120 or the second driver 130 may be embedded in the display panel 110. For example, the first driver 120 or a part of the first driver 120 may be disposed and/or formed in the non-display area NDA and disposed on the substrate SUB of the display panel 110.

Although FIGS. 10 and 11 illustrate that the first driver 120 is formed on a side of the display area DA (e.g., in the non-display area NDA on the right side of the display area DA), but embodiments are not limited thereto. For example, the first driver 120 may be positioned only on the other side (e.g., the non-display area NDA on the left side of the display area DA) of the display area DA, or may be positioned on sides (e.g., the non-display area NDA on the left side and right side of the display area DA) of the display area DA. In another example, a part of the first driver 120 may be portioned in the non-display area NDA, and another part of the first driver 120 may be positioned in a non-emission area (e.g., an area between emission areas of the pixels PX) inside the display area DA.

In an embodiment, the other driver of the first driver 120 and the second driver 130 or a part of the other driver may be disposed or formed outside the display panel 110 to be electrically connected to the display panel 110. For example, the second driver 130 may be implemented as a multiple number of integrated circuit chips, which may be disposed on the circuit boards 140 electrically connected to the pixels PX of the display panel 110. The second driver 130 may be implemented as at least one integrated circuit chip and mounted on the non-display area NDA of the display panel 110.

The circuit board 140 may be connected to the display panel 110 through the pads PD. In an embodiment, the circuit board 140 may be a flexible film such as a flexible printed circuit board (FPCB), a printed circuit board (PCB), or a chip on film (COF), but embodiments are not limited thereto. In an embodiment, the circuit board 140 may be connected to the timing controller and/or the power supply unit through another circuit board, connector, or the like.

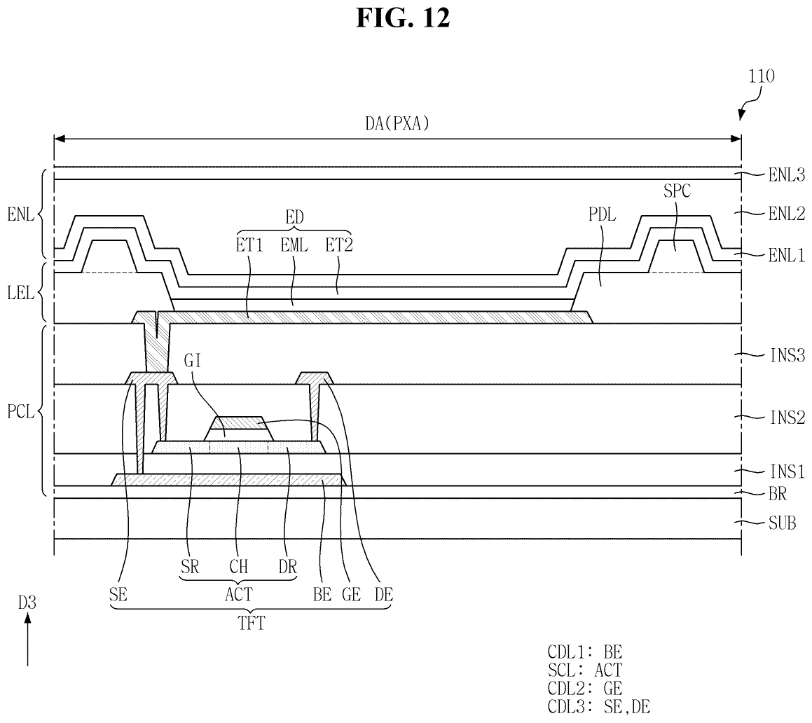

FIG. 12 is a schematic cross-sectional view illustrating the display panel 110 according to an embodiment. For example, FIG. 12 shows a part of the display area DA of the display panel 110. FIG. 12 illustrates a light emitting display panel including the light emitting element ED (e.g., an organic light emitting diode) as an example of the display panel 110 to which embodiments may be applied.

Referring to FIG. 12, the display panel 110 according to an embodiment may include the substrate SUB, a panel circuit layer PCL, a light emitting element layer LEL, and an encapsulation layer ENL. The panel circuit layer PCL, the light emitting element layer LEL, and the encapsulation layer ENL may be disposed to overlap each other on the substrate SUB. For example, with respect to the display area DA, the panel circuit layer PCL, the light emitting element layer LEL, and the encapsulation layer ENL may be sequentially disposed on the substrate SUB along the third direction D3. The positions of the panel circuit layer PCL, the light emitting element layer LEL, and/or the encapsulation layer ENL may change according to embodiments.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB, which is a base member for forming the display panel 110, may be a rigid or flexible substrate (or film). In an embodiment, the substrate SUB may be a substrate including an insulating material such as glass or the like and having rigid characteristics, and may not be bent. In another example, the substrate SUB may be a flexible substrate that includes polyimide or another insulating material and may be transformed to be bent, folded, or rolled, and may or may not be bent. The type and/or material of the substrate SUB may change according to embodiments.

The panel circuit layer PCL (for example, a pixel circuit layer or a thin film transistor layer) may be disposed on the substrate SUB. The panel circuit layer PCL may include circuit elements (e.g., transistors and at least one capacitor) constituting the pixel circuit of each pixel PX, and wires (e.g., signal lines and power lines). In an embodiment, the panel circuit layer PCL may further include circuit elements (e.g., driving transistors and/or driving capacitors provided in the first driver 120) of the first driver 120. In an embodiment, the transistors disposed in the panel circuit layer PCL may be thin film transistors formed by a thin film deposition process.

FIG. 12 shows one thin film transistor TFT disposed in one pixel area PXA, as an example of the circuit elements that are provided in the panel circuit layer PCL. The thin film transistor TFT of FIG. 12 may be a driving transistor or a switching transistor provided in the pixel circuit of the corresponding pixel PX.

In an embodiment, the panel circuit layer PCL may include a barrier layer BR. In an example, the barrier layer BR may be disposed on the substrate SUB, and circuit elements and wires may be disposed on the barrier layer BR.

The panel circuit layer PCL may include at least one semiconductor layer SCL and conductive layers disposed on the barrier layer BR. Electrodes constituting the circuit elements of the panel circuit layer PCL, conductive patterns (e.g., bridge electrodes) and/or wires connected to the circuit elements, and the like may be provided in the conductive layers. The active layers ACT of the thin film transistors TFT provided in the panel circuit layer PCL may be provided in the semiconductor layer SCL.

In an embodiment, the panel circuit layer PCL may include a first conductive layer CDL1 (e.g., a bottom conductive layer), the semiconductor layer SCL (e.g., an oxide semiconductor layer), a second conductive layer CDL2 (e.g., a gate conductive layer), and a third conductive layer CDL3 (e.g., a source-drain conductive layer or a data conductive layer), which are sequentially disposed on the barrier layer BR (or the substrate SUB) along the third direction D3. Insulating layers and/or insulating patterns may be disposed between the semiconductor layer SCL and the conductive layers of the panel circuit layer PCL.

Patterns (e.g., electrodes, conductive patterns, and/or wires of each conductive layer) included in each conductive layer of the panel circuit layer PCL may include at least one conductive material. For example, the patterns provided on each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material.

In an embodiment, each pattern provided on each conductive layer of the panel circuit layer PCL may have a single-layer structure or a multilayer structure. For example, each of the patterns provided in the first conductive layer CDL1, the second conductive layer CDL2, and the third conductive layer CDL3 may have a single-layer structure or a multilayer structure. In an embodiment, the patterns included in the same conductive layer may be simultaneously formed of the same material, and may have the same cross-sectional structure.

The panel circuit layer PCL may further include insulating layers and/or insulating patterns disposed on the substrate SUB. For example, the panel circuit layer PCL may include the barrier layer BR, a first insulating layer INS1 (e.g., a buffer layer), a gate insulating layer GI, a second insulating layer INS2 (e.g., an interlayer insulating layer), and a third insulating layer INS3 (e.g., a planarization layer) sequentially disposed on the substrate SUB along the third direction D3.

In an embodiment, at least one insulating layer provided in the panel circuit layer PCL may be disposed (e.g., entirely disposed) in the display area DA. For example, the barrier layer BR, the first insulating layer INS1, the second insulating layer INS2, and the third insulating layer INS3 may be disposed (e.g., entirely disposed) in the display area DA.

The gate insulating layer GI may be partially disposed only in each pixel area PXA and a portion of the display area DA including the pixel area PXA, or may be disposed over the entire display area DA. In the embodiment of FIG. 12, the gate insulating layer GI may be partially disposed only in each pixel area PXA and a portion of the display area DA including the same.

The barrier layer BR may be disposed between the substrate SUB and the first conductive layer CDL1. The barrier layer BR may include at least one inorganic insulating layer including an inorganic insulating material (e.g., silicon nitride, silicon oxide, silicon oxynitride, titanium oxide, aluminum oxide, or another inorganic insulating material). The barrier layer BR may protect the pixels PX from moisture permeating through the substrate SUB that is susceptible to moisture permeation. The material of the barrier layer BR may be variously changed according to embodiments.

The first insulating layer INS1 may be disposed on the first conductive layer CDL1. For example, the first insulating layer INS1 may be disposed on the barrier layer BR (or the substrate SUB) and cover the patterns of the first conductive layer CDL1. The first insulating layer INS1 may include at least one inorganic insulating layer including an inorganic insulating material (e.g., silicon nitride, silicon oxide, silicon oxynitride, titanium oxide, aluminum oxide, or another inorganic insulating material).

The gate insulating layer GI may be disposed on the semiconductor layer SCL. The gate insulating layer GI may include at least one inorganic insulating layer including an inorganic insulating material.

In an embodiment, the gate insulating layer GI may be disposed on only a part of the semiconductor layer SCL. For example, the gate insulating layer GI may be disposed on a portion of the active layer ACT included in each thin film transistor TFT. For example, the gate insulating layer GI may be disposed only on a portion of the active layer ACT including a channel region CH, and may expose another portion of the active layer ACT including at least one portion of each of a source region SR and a drain region DR.

As the gate insulating layer GI exposes the source region SR and the drain region DR, the source region SR and the drain region DR may be appropriately and/or readily conductive during the manufacturing process of the display panel 110. For example, in the step of etching the gate insulating layer GI to expose at least a part of the source region SR and at least a part of the drain region DR, oxygen vacancies may occur in the source region SR and the drain region DR. Accordingly, the source region SR and the drain region DR may be appropriately conductive in a subsequent process (e.g., a process of forming the second insulating layer INS2, etc.) without performing a separate doping process.

The second insulating layer INS2 may be disposed on the first insulating layer INS1, the semiconductor layer SCL, the gate insulating layer GI, and the second conductive layer CDL2. For example, the second insulating layer INS2 may be disposed on the first insulating layer INS1 and cover the patterns of the semiconductor layer SCL, the gate insulating layer GI, and the second conductive layer CDL2. The second insulating layer INS2 may include at least one inorganic insulating layer including an inorganic insulating material.

The third insulating layer INS3 may be disposed on the third conductive layer CDL3. For example, the third insulating layer INS3 may be disposed on the second insulating layer INS2 and cover the patterns of the third conductive layer CDL3. The third insulating layer INS3 may include at least one organic insulating layer including an organic insulating material (e.g., acryl resin, epoxy resin, phenolic resin, polyamide resin, polyimide resin, or other organic insulating materials). The third insulating layer INS3 may include an inorganic insulating layer or may not include an inorganic insulating layer. The surface (for example, the top surface) of the third insulating layer INS3 may be substantially flat.

The thin film transistor TFT may include the active layer ACT and a gate electrode GE overlapping the active layer ACT. In an embodiment, the gate electrode GE may be disposed on a part of the active layer ACT. For example, the gate electrode GE may be a top-gate electrode.

In an embodiment, the thin film transistor TFT may further include at least one of the source electrode SE or the drain electrode DE. For example, the thin film transistor TFT may further include the source electrode SE connected to the source region SR, and the drain electrode DE connected to the drain region DR. In another example, the thin film transistor TFT may not include a separate source electrode and/or a separate drain electrode, and the source region SR and/or the drain region DR may be connected to another circuit element, wire, and/or conductive pattern to function as the source electrode and/or the drain electrode of the thin film transistor TFT.

In an embodiment, the thin film transistor TFT may further include a bottom electrode BE (or a light blocking layer) disposed below the active layer ACT. In an embodiment, the bottom electrode BE may be connected to an electrode (e.g., the source electrode SE) of the thin film transistor TFT, and may be used as a back-gate electrode (or a bottom-gate electrode) for adjusting the characteristics of the thin film transistor TFT. For example, the bottom electrode BE may be electrically connected to the source electrode SE of the thin film transistor TFT through at least one contact hole penetrating the first insulating layer INS1 and the second insulating layer INS2. Since the bottom electrode BE is disposed under the active layer ACT, it is possible to block external light from being incident on the channel region CH, and stabilize the operating characteristics of the thin film transistor TFT.

FIG. 12 illustrates an embodiment in which the thin film transistor TFT is formed in a double-gate structure including the bottom electrode BE and the gate electrode GE that overlap each other with the active layer ACT interposed therebetween, but embodiments are not limited thereto. For example, the thin film transistor TFT may include only one of the bottom electrode BE and the gate electrode GE. In an example, the thin film transistor TFT may be formed in a top-gate structure including the single gate electrode GE disposed above the active layer ACT, or may be formed in a bottom-gate structure including the bottom electrode BE disposed below the active layer ACT.

In an embodiment, the thin film transistor TFT may be an oxide transistor. For example, the thin film transistor TFT may be an N-type oxide transistor.

In an embodiment, the thin film transistor TFT may be manufactured using the sputtering target 20A or 20B according to the embodiment of FIG. 5 or FIG. 8, and may include a sputtering material included in the sputtering target 20A or 20B. For example, the active layer ACT of the thin film transistor TFT may be formed by etching the thin film 42 formed using the sputtering target 20A or 20B according to the embodiment of FIG. 5 or FIG. 8, and may include indium-gallium-zinc oxide (IGZO).

The bottom electrode BE may be provided in the first conductive layer CDL1 disposed on the barrier layer BR (or the substrate SUB). For example, the bottom electrode BE may be disposed between the barrier layer BR (or substrate SUB) and the first insulating layer INS1.

The bottom electrode BE may overlap the active layer ACT and the gate electrode GE. For example, the bottom electrode BE may be disposed under the active layer ACT to overlap at least a part of the active layer ACT including the channel region CH, and may face the gate electrode GE with the active layer ACT interposed therebetween.

The active layer ACT may be provided in the semiconductor layer SCL. For example, the active layer ACT may be disposed on the first insulating layer INS1, and covered with the gate insulating layer GI.

The active layer ACT may include the channel region CH, and the source region SR and the drain region DR spaced apart from each other with the channel region CH interposed therebetween. For example, the source region SR and the drain region DR may be positioned on sides (e.g., opposite sides) of the channel region CH. The source region SR and the drain region DR may have a carrier concentration (e.g., electron concentration) higher than that of the channel region CH.

The active layer ACT may overlap the bottom electrode BE and the gate electrode GE. For example, a portion of the active layer ACT including the channel region CH may overlap the bottom electrode BE and the gate electrode GE in the third direction D3.

In an embodiment, the active layer ACT may include an oxide semiconductor. For example, the active layer ACT may include an oxide semiconductor including at least one of indium (In), gallium (Ga), zinc (Zn), tin (Sn), or hafnium (Hf), or other oxide semiconductors. As an example, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or other oxide semiconductors. In an embodiment, the active layer ACT may be formed from the thin film 42 formed using the sputtering target 20A or 20B according to the embodiment of FIG. 5 or FIG. 8, and may include indium-gallium-zinc oxide (IGZO). The material of the active layer ACT and the sputtering material of the sputtering target 20A or 20B for forming the active layer ACT may vary according to embodiments.

The gate insulating layer GI may be disposed on the active layer ACT. For example, the gate insulating layer GI may be disposed on a portion of the active layer ACT including the channel region CH.

The gate electrode GE may be disposed on the gate insulating layer GI. For example, the gate electrode GE may be disposed on the gate insulating layer GI in a first transistor region in which a first transistor T1 is disposed. The gate electrode GE may be provided in the second conductive layer CDL2. The second conductive layer CDL2 may be disposed on the gate insulating layer GI, and may be covered by the second insulating layer INS2.

The gate electrode GE may be disposed on the active layer ACT. For example, the gate electrode GE may be disposed on the gate insulating layer GI covering the channel region CH. The gate electrode GE and the active layer ACT may be separated from each other with the gate insulating layer GI interposed therebetween.

The source electrode SE and the drain electrode DE may be provided in the third conductive layer CDL3. The third conductive layer CDL3 may be disposed on the second insulating layer INS2 covering the second conductive layer CDL2 and the like, and may be covered with the third insulating layer INS3.

The source electrode SE may be connected to a part of the active layer ACT. For example, the source electrode SE may be electrically connected to the source region SR through at least one contact hole penetrating the second insulating layer INS2. In an embodiment, the source electrode SE may also be electrically connected to the bottom electrode BE through at least one contact hole penetrating the first insulating layer INS1 and the second insulating layer INS2.

The drain electrode DE may be connected to another part of the active layer ACT. For example, the drain electrode DE may be electrically connected to the drain region DR through at least one contact hole penetrating the second insulating layer INS2.

At least one thin film transistor TFT provided in each pixel PX may be electrically connected to the light emitting element ED of the corresponding pixel PX. For example, an electrode (e.g., the source electrode SE) of the thin film transistor TFT may be electrically connected to a first electrode ET1 of the light emitting element ED.

The third conductive layer CDL3 including the source electrode SE, the drain electrode DE, and/or the like may be covered with the third insulating layer INS3.

The light emitting element layer LEL may be disposed on the panel circuit layer PCL. For example, the light emitting element layer LEL may be disposed on the third insulating layer INS3, and may be positioned at least in the display area DA.

The light emitting element layer LEL may include the light emitting element ED for each of the pixels PX. For example, the light emitting element layer LEL may include a pixel defining film PDL (also referred to as “bank”) that partitions the emission areas of the pixels PX and the light emitting element ED disposed in each emission area. In an embodiment, the light emitting element layer LEL may further include a spacer SPC disposed on a part of the pixel defining film PDL.

The light emitting element ED may include a first electrode ET1 positioned in each emission area, and a light emitting layer EML and a second electrode ET2 sequentially disposed on the first electrode ET1. The first electrode ET1 of the light emitting element ED may be connected to at least one thin film transistor TFT included in the corresponding pixel PX.

The first electrode ET1 of the light emitting element ED may be a single-layer structure or a multi-layer electrode including at least one conductive material. In an embodiment, the display panel 110 may be a top emission type display panel, and the first electrode ET1 may include a reflective electrode layer having high reflectivity.

The light emitting layer EML of the light emitting element ED may include a high molecular material or a low molecular material. Light emitted from the light emitting layer EML may contribute to image display.

Although FIG. 12 illustrates the display panel 110 in which the light emitting layer EML of the light emitting element ED is individually formed in each pixel area PXA, embodiments are not limited thereto. For example, the display panel 110 may include the light emitting elements having a tandem structure including the light emitting layer EML formed as a common layer over the entire display area DA.

The second electrode ET2 of the light emitting element ED may include a conductive material. In an embodiment, the second electrode ET2 may be a common layer formed across the entire display area DA to cover the light emitting layer EML and the pixel defining film PDL. In an embodiment, the display panel 110 may be a top emission type display panel, and the second electrode ET2 may include a transparent or translucent electrode layer.

The pixel defining film PDL may have an opening corresponding to each emission area and may surround the emission area. For example, the pixel defining film PDL may be formed to cover an edge portion of the first electrode ET1 of the light emitting element ED and may include an opening exposing the remaining portion of the first electrode ET1. A region where the exposed first electrode ET1 and the light emitting layer EML overlap may correspond to the emission area of each pixel PX. In an embodiment, the pixel defining film PDL may include at least one organic insulating layer including an organic insulating material.

The spacer SPC may be disposed on a part of the pixel defining film PDL. The spacer SPC may include at least one organic insulating layer including an organic insulating material. The spacer SPC may include the same material as the pixel defining film PDL or may include a different material from the pixel defining film PDL. The pixel defining film PDL and the spacer SPC may be sequentially formed through individual mask processes, or may be simultaneously and/or integrally formed using a halftone mask.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. The encapsulation layer ENL may block the permeation of oxygen or moisture into the light emitting element layer LEL, and may reduce electrical and/or physical impacts to the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

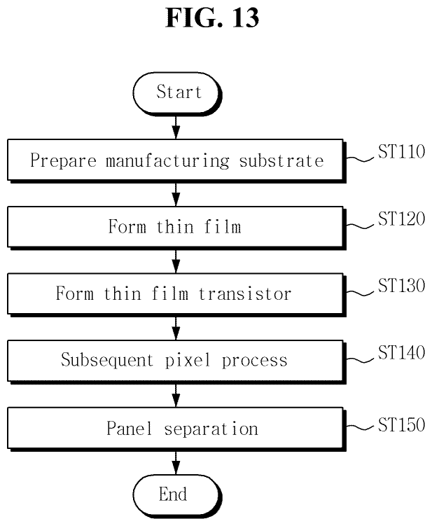

FIG. 13 is a flowchart illustrating a method for manufacturing the display device 100 according to an embodiment. For example, FIG. 13 schematically shows the manufacturing steps of the display device 100 for manufacturing the display panel 110 of FIGS. 10 to 12.

In an embodiment, the display panels 110 may be simultaneously manufactured on a manufacturing substrate, and the thin film transistors TFT provided in the display panels 110 may be formed using the sputtering target 20A and/or 20B according to at least one of the above-described embodiments.

Referring to FIGS. 10 to 13 in addition to FIGS. 1 to 9, the manufacturing substrate may be prepared (step ST110). In an embodiment, the manufacturing substrate may include unit areas, and the unit areas may be areas in which the display panels 110 are to be formed. For example, the manufacturing substrate may be a mother substrate (e.g., a manufacturing substrate in which the substrates SUB of the display panels 110 are connected without being separated) for simultaneously manufacturing the display panels 110, and the unit areas may be cell areas respectively corresponding to the display panels 110. In an embodiment, before forming the thin film transistors TFT on the manufacturing substrate (e.g., a mother substrate), at least one insulating layer (e.g., the barrier layer BR and/or the first insulating layer INS1) and/or a conductive layer (e.g., the first conductive layer CDL1 or the light blocking layer) may be formed.

Thereafter, the thin film 42 may be formed on the manufacturing substrate (step ST120). In an embodiment, the thin film 42 may be formed on the manufacturing substrate using the sputtering target 20A and/or 20B including the first sputtering target segment 20A_1 and/or 20B_1 and the second sputtering target segment 20A_2 and/or 20B_2 with different composition ratios of the sputtering material as in the embodiment of FIG. 5 or FIG. 8. For example, the thin film 42 may be formed on the manufacturing substrate by the thin film forming method (e.g., thin film deposition by a sputtering method) according to the embodiment of FIG. 9.

For example, the manufacturing substrate, which serves as the target substrate 40, may be disposed in the sputtering apparatus 1A and/or 1B to face the sputtering target 20A and/or 20B, and the thin film 42 may be deposited on the manufacturing substrate. The first sputtering target segment 20A_1 and/or 20B_1 and the second sputtering target segment 20A_2 and/or 20B_2 of the sputtering target 20A and/or 20B may be disposed above different portions of the manufacturing substrate. For example, the sputtering target 20A and/or 20B may include at least two first sputtering target segments 20A_1 and/or 20B_1 positioned at the edge portions in the first direction D1 and at least one second sputtering target segment 20A_2 and/or 20B_2 (e.g., the second sputtering target segments 20A_2 and/or 20B_2) positioned at the central portion in the first direction D1. In an embodiment, each sputtering target segment 20A_1, 20A_2, 20B_1, and/or 20B_2 may face at least one cell area (or a portion of the cell area).

In an embodiment, the sputtering targets 20A and 20B may include indium (In), gallium (Ga), and zinc (Zn). For example, the sputtering targets 20A and 20B may include indium-gallium-zinc oxide (IGZO). The thin film 42 deposited using the sputtering target 20A and/or 20B may include indium-gallium-zinc oxide (IGZO).

In an embodiment, the composition ratio of zinc (Zn) included in the first sputtering target segments 20A_1 and 20B_1 may be higher than the composition ratio of zinc (Zn) included in the second sputtering target segments 20A_2 and 20B_2, and the composition ratio of indium (In) and gallium (Ga) included in the first sputtering target segments 20A_1 and 20B_1 may be lower than the composition ratio of indium (In) and gallium (Ga) included in the second sputtering target segments 20A_2 and 20B_2. Accordingly, although the plasma non-uniformity or the like occurs, the thin film 42 having overall uniform characteristics may be formed on the manufacturing substrate. For example, the thin film 42 may exhibit uniform characteristics in the composition ratio of indium (In), gallium (Ga), and zinc (Zn) throughout the entire area including the edge portion 42_1 corresponding to the first sputtering target segment 20A_1 and/or 20B_1 and the other portion (or central portion) 42_2 corresponding to the second sputtering target segment 20A_2 and/or 20B_2. Accordingly, the characteristic deviation of the thin film 42 formed on the manufacturing substrate may be prevented or reduced. As a result, the characteristic deviation of the display panels 110 including the thin film transistors TFT formed using the thin film 42 may also be prevented or reduced.

Thereafter, the thin film transistor TFT may be formed on the manufacturing substrate using the thin film 42 (step ST130). For example, by etching the thin film 42, the active layers ACT may be formed in each of the unit areas on the manufacturing substrate, and the thin film transistors TFT including the active layers ACT may be formed. In an example, after the formation of the active layers ACT, a process for forming the gate insulating layers GI, the gate electrodes GE, the second insulating layer INS2, the source electrodes SE and/or the drain electrodes DE on the active layers ACT may be performed to form the transistors TFT in each of the unit areas.

Although the thin film forming step ST120 and the thin film transistor forming step ST130 are described separately with reference to FIG. 13, embodiments are not limited thereto. For example, the thin film forming step ST120 may be considered to be included in the thin film transistor forming step ST130.

Subsequently, a subsequent pixel process may be performed (step ST140). In an embodiment, in case that a light emitting display device is to be manufactured, an insulating layer (e.g., the third insulating layer INS3 of FIG. 12) covering the thin film transistors TFT may be formed, and the light emitting elements ED of the pixels PX may be formed or disposed on the insulating layer. For example, a process of forming the encapsulation layer ENL covering the light emitting elements ED may be added.

Thereafter, a panel separation process may be performed (step ST150). For example, the display panels 110 manufactured on a manufacturing substrate (e.g., single manufacturing substrate) may be separated individually. Accordingly, the display panel 110 of each display device 100 may be manufactured.

Although FIG. 13 illustrates an embodiment in which the display panels 110 are manufactured simultaneously using the manufacturing substrate, embodiments are not limited thereto. For example, each display panel 110 may be formed on each individually separated substrate SUB. Even in this case, as in the embodiments described above, each display panel 110 may be manufactured using the sputtering target 20A and/or 20B including the first sputtering target segment 20A_1 and/or 20B_1 and the second sputtering target segment 20A_2 and/or 20B_2 with different composition ratios of the sputtering material. Accordingly, the thin film 42 having uniform characteristics may be formed in the thin film deposition area (e.g., the display area DA) of the display panel 110, and the characteristic deviation of the pixels PX may be prevented or reduced.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

What is claimed is:

1. A sputtering apparatus comprising:
a chamber providing a sputtering space;
a sputtering target mounted in the chamber, and including a sputtering material; and
a target substrate facing the sputtering target,
wherein the sputtering target comprises a first sputtering target segment disposed in a first portion and a second sputtering target segment disposed in a second portion, and
a composition ratio of the sputtering material in the first sputtering target segment is different from a composition ratio of the sputtering material in the second sputtering target segment.

2. The sputtering apparatus of claim 1, further comprising:
a shield disposed between the sputtering target and the target substrate and exposing a thin film deposition surface of the target substrate,
wherein the first sputtering target segment is disposed closer to the shield than the second sputtering target segment.

3. The sputtering apparatus of claim 1, wherein
the sputtering material includes zinc (Zn), and
a composition ratio of zinc (Zn) included in the first sputtering target segment is higher than a composition ratio of zinc (Zn) included in the second sputtering target segment.

4. The sputtering apparatus of claim 3, wherein the composition ratio of zinc (Zn) included in the first sputtering target segment is in a range of about 4% to about 7% higher than the composition ratio of zinc (Zn) included in the second sputtering target segment.

5. The sputtering apparatus of claim 3, wherein
the sputtering material further includes indium (In) and gallium (Ga), and
a composition ratio of indium (In) and gallium (Ga) included in the first sputtering target segment is lower than a composition ratio of indium (In) and gallium (Ga) included in the second sputtering target segment.

6. The sputtering apparatus of claim 5, wherein a composition ratio of indium (In) included in the first sputtering target segment is in a range of about 2% to about 5% lower than a composition ratio of indium (In) included in the second sputtering target segment.

7. The sputtering apparatus of claim 5, wherein a composition ratio of gallium (Ga) included in the first sputtering target segment is in a range of about 2% to about 5% lower than a composition ratio of gallium (Ga) included in the second sputtering target segment.

8. The sputtering apparatus of claim 1, wherein
the first portion comprises an edge portion of the sputtering target, and
the second portion comprises a central portion of the sputtering target.

9. The sputtering apparatus of claim 8, wherein the first portion is disposed at edge portions of the sputtering target in a first direction.

10. The sputtering apparatus of claim 9, wherein the sputtering target comprises a plurality of first sputtering target segments disposed in edge portions of the sputtering target in the first direction, and a plurality of second sputtering target segments disposed between the plurality of first sputtering target segments.

11. The sputtering apparatus of claim 1, wherein the target substrate is a manufacturing substrate for manufacturing a plurality of display panels.

12. The sputtering apparatus of claim 11, wherein the sputtering target includes an oxide semiconductor material for forming oxide transistors of the plurality of display panels.

13. The sputtering apparatus of claim 12, wherein
the sputtering material includes indium (In), gallium (Ga), and zinc (Zn), and
a thin film deposited on the target substrate using the sputtering target includes indium-gallium-zinc oxide (IGZO).

14. A sputtering target comprising:
a first sputtering target segment disposed in a first portion and including a sputtering material; and
a second sputtering target segment disposed in a second portion and including the sputtering material,
wherein a composition ratio of the sputtering material in the first sputtering target segment is different from a composition ratio of the sputtering material in the second sputtering target segment.

15. The sputtering target of claim 14, wherein
the sputtering material includes indium (In), gallium (Ga), and zinc (Zn), and
a composition ratio of zinc (Zn) included in the first sputtering target segment is higher than a composition ratio of zinc (Zn) included in the second sputtering target segment.

16. The sputtering target of claim 15, wherein a composition ratio of indium (In) and gallium (Ga) included in the first sputtering target segment is lower than a composition ratio of indium (In) and gallium (Ga) included in the second sputtering target segment.

17. The sputtering target of claim 14, wherein
the first portion comprises an edge portion of the sputtering target, and
the second portion comprises a central portion of the sputtering target.

18. A method for manufacturing a display device, comprising:
preparing a manufacturing substrate;
forming a thin film using a sputtering target comprising a first sputtering target segment and a second sputtering target segment disposed on different portions of the manufacturing substrate, the thin film including a sputtering material of the sputtering target on the manufacturing substrate; and
forming thin film transistors on the manufacturing substrate using the thin film,
wherein a composition ratio of the sputtering material in the first sputtering target segment is different from a composition ratio of the sputtering material in the second sputtering target segment.

19. The method of claim 18, wherein
the sputtering target includes indium (In), gallium (Ga), and zinc (Zn), and
the thin film includes indium-gallium-zinc oxide (IGZO).

20. The method of claim 19, wherein
a composition ratio of zinc (Zn) included in the first sputtering target segment is higher than a composition ratio of zinc (Zn) included in the second sputtering target segment, and
a composition ratio of indium (In) and gallium (Ga) included in the first sputtering target segment is lower than a composition ratio of indium (In) and gallium (Ga) included in the second sputtering target segment.
